(19) United States
(12) Patent Application Publication
(10) Pub. No.: US 2008/0157372 A1
(43) Pub. Date: Jul. 3, 2008

(54) Metal Line of Semiconductor Device and Manufacturing Method Thereof

(76) Inventors: SUNG JOONG JOO, Seo-gu (KR); Han Choon Lee, Songpa-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/862,281

(22) Filed: Sep. 27, 2007

(30) Foreign Application Priority Data
Dec. 27, 2006 (KR) 10-2006-0135710

(51) Int. Cl. H01L 23/52; H01L 21/4763

(52) U.S. Cl. 257/751; 438/653; 257/E23.01; 257/E21.495

(57) ABSTRACT

Provided is a method for forming a metal line of a semiconductor device. A trench is formed in an interlayer insulating layer formed on a semiconductor substrate. Copper is deposited in the trench to form a copper metal line, and a diffusion barrier layer is formed on the interlayer insulating layer and the copper metal line. A metal pad is formed on the diffusion barrier layer. In one embodiment, the diffusion barrier layer is formed of three layers, including TiSiN layers.

### CROSS-REFERENCE TO RELATED APPLICATION

The present application claims the benefit under 35 U.S.C. §119 of Korean Patent Application No. 10-2006-0135710, filed Dec. 27, 2006, which is hereby incorporated by reference in its entirety.

### BACKGROUND

A trend towards high speed and high integration of semiconductor devices are under rapid progress, which reduces the size of a transistor more and more. As the integration degree of a transistor increases, a line of a semiconductor device becomes finer, and consequently a signal applied to a line tends to become delayed or distorted, which hinders the high speed operation of a semiconductor device.

For this reason, recently, copper is being used as a line material of a semiconductor device. Copper has a lower resistance and higher electro-migration than aluminum or aluminum alloys, which have been widely used as the line material of a semiconductor device.

In the case where a copper line is used for a semiconductor device, it is difficult to electrically connect a lead frame serving as a terminal for delivering a signal from an outside to a semiconductor device. Particularly, a lead frame and a copper line are difficult to wire-bond through an aluminum wire or a gold line wire.

### BRIEF SUMMARY

Embodiments of the present invention provide a method for forming a metal line of a semiconductor device, that can inhibit diffusion of copper ions of a copper metal line into an aluminum line by forming a plurality of TiSiN layers as a diffusion barrier layer between the copper metal line and the aluminum line.

In one embodiment, a method for forming a metal line of a semiconductor device includes: forming a trench in an interlayer insulating layer formed on a semiconductor substrate; depositing copper in the trench to form a copper metal line; forming a diffusion barrier layer including at least one barrier layer on the interlayer insulating layer and the copper metal line; and forming a metal pad on the diffusion barrier layer.

In another embodiment, a metal line of a semiconductor device includes: a semiconductor substrate including an interlayer insulating layer; a trench formed in the interlayer insulating layer; a copper metal line formed in the trench; a diffusion barrier layer formed on the interlayer insulating layer and the copper metal line; and a metal pad formed on the diffusion barrier layer, wherein the diffusion barrier layer includes a TiN layer and at least one TiSiN layer formed on the TiN layer.

The details of one or more embodiments are set forth in the accompanying drawings and the description below. Other features will be apparent from the description and drawings, and from the claims.

### BRIEF DESCRIPTION OF THE DRAWINGS

FIGS. 1 to 6 are cross-sectional views illustrating a method for forming a metal line of a semiconductor device according to an embodiment.

### DETAILED DESCRIPTION

A metal line of a semiconductor device and a forming method thereof according to embodiments of the present invention will be described below with reference to the accompanying drawings.

FIG. 6 is a cross-sectional view illustrating a metal line of a semiconductor device according to an embodiment.

Referring to FIG. 6, the metal line can include a copper metal line 30 formed in a trench in an interlayer insulating layer 10. The copper metal line 30 can be formed on a lower line 20 or other structures. A diffusion barrier layer can be formed on the copper metal line 30. In one embodiment, the diffusion barrier layer includes a TiN layer 40 and at least one TiSiN layer 51 and 61 on the TiN layer 40. A metal pad 71 can be formed on the copper metal line 30 with the diffusion barrier layer interposed therebetween.

The metal pad 71 can be formed of aluminum and can be wire-bonded through an aluminum wire or a gold line wire.

The diffusion barrier layer can include the TiN layer 40, a first TiSiN layer 51, and a second TiSiN layer 61 to inhibit copper contained in the copper metal line 30 from diffusing into the metal pad 71.

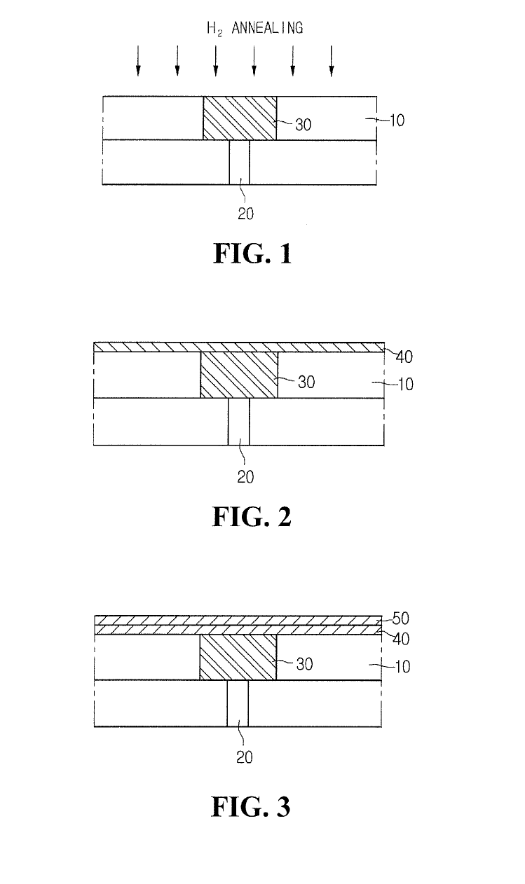

FIGS. 1 to 6 are cross-sectional views illustrating a method for forming a metal line of a semiconductor device according to an embodiment.

Referring to FIG. 1, an interlayer insulating layer 10 can be formed on a semiconductor substrate including a lower line 20. For example, the interlayer insulating layer 10 can be an oxide layer or a nitride layer. Also, the lower line 20 can be formed of copper or aluminum.

The semiconductor substrate can include a semiconductor device such as a metal oxide semiconductor (MOS) transistor and other structures.

The copper metal line 30 can be formed to pass through the interlayer insulating layer 10 and connect with the lower line 20.

Therefore, a trench can be formed in the interlayer insulating layer 10 by photolithography and etching processes. For example, a photoresist film (not shown) can be coated on the interlayer insulating layer 10, and then patterned using a mask that defines a trench of a damascene process or a via region to expose the lower line 20.

Copper can be used to gap-fill the trench of the interlayer insulating layer 10 through an electroplating process, and the resulting structure is planarized using a chemical mechanical polishing (CMP) process until the surface of the interlayer insulating layer 10 is exposed, thereby forming the copper metal line 30. In some embodiments, barrier metal (not shown) and a copper seed layer (not shown) can be formed before copper gap-fills the trench.

Referring again to FIG. 1, an annealing process is performed on the surface of the semiconductor substrate including the copper metal line 30.

When the copper metal line 30 is exposed to an atmosphere, a portion of the copper metal line 30 reacts with oxygen contained in the atmosphere to form a natural oxide layer.

Therefore, the annealing process using a hydrogen gas (H₂) is performed to remove the natural oxide layer formed on the copper metal line 30. For example, the annealing process can be performed for 1-45 seconds with the conditions of temperature of 100-350° C. and pressure of 10-25 Torr.

Subsequently, a first heating process is performed to prepare the substrate for TiN deposition. The heating process can be performed for 1-15 seconds under pressure of 1-10 Torr.

Referring to FIG. 2, after the first heating process is completed, the first TiN layer 40 can be deposited on the metal line 30 using a first heat treatment process. For example, the deposition of the first TiN layer 40 can be performed using a heat treatment process at a temperature of 100-350° C. and a pressure of 1-5 Torr for 5-32 seconds.

Next, a second heating process can be performed for heating the semiconductor substrate including the first TiN layer 40 so that a subsequent deposition of TiN can be easily performed. In one embodiment, the heating process can be performed at pressure of 1-10 Torr for 1-15 seconds.

Referring to FIG. 3, after the second heating process is completed, a second TiN layer 50 can be deposited on the first TiN layer 40 using a second heat treatment process. The deposition of the second TiN layer 50 can be performed using a heat treatment process at a temperature of 100-350° C. and a pressure of 1-5 Torr for 5-32 seconds.

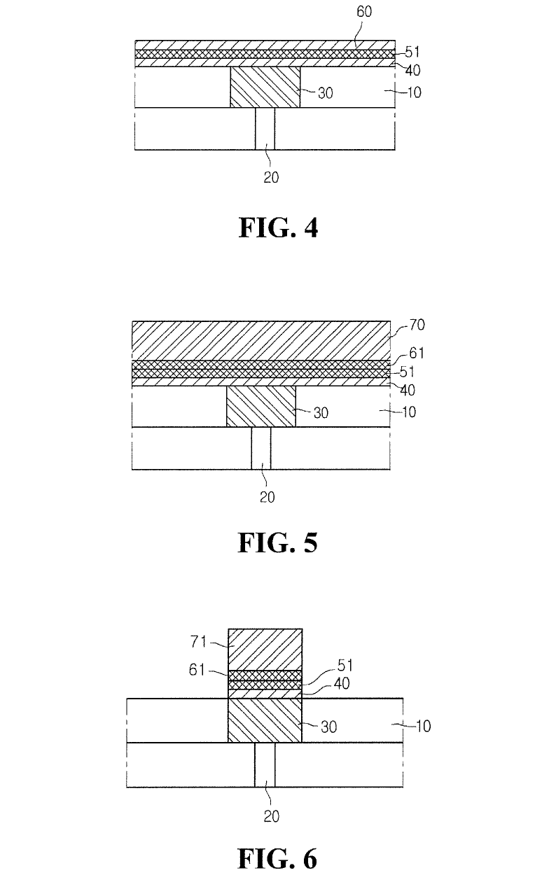

Referring to FIG. 4, a plasma treatment or a high temperature heat treatment can then be performed including injecting a silane gas (SiH₄) onto the second TiN layer 50. Accordingly, the second TiN layer 50 changes into a TiSiN layer 51 containing a predetermined amount of silicon groups. In one embodiment, 10-40 sccm of a silane gas is injected at a temperature of 100-350° C.

Here, copper ions can be diffused by the first and second heat treatments. At this point, since the silane gas is injected, the copper ions can be removed.

According to an embodiment, at this point, the semiconductor substrate including the TiSiN layer 51 can be maintained in a holding chamber for about one minute.

After that, a third heating process for heating the semiconductor substrate including the TiSiN layer 51 can be performed so that a subsequent deposition of TiN can be easily performed. In one embodiment, the heating process can be performed at 10 Torr for 15 seconds.

After the third heating process is completed, a third TiN layer 60 is deposited on the TiSiN layer 51 using a heat treatment process. The deposition of the third TiN layer 60 can be performed using a heat treatment process at a temperature of 100-350° C. and a pressure of 1-5 Torr for 5-32 seconds.

Then, a plasma treatment or a high temperature heat treatment can be performed including injecting a silane gas (SiH₄) onto the third TiN layer 60 to change the third TiN layer 60 into a TiSiN layer 61 containing a predetermined amount of silicon groups. In an embodiment, about 10-40 sccm of a silane gas is injected at temperature of 100-350° C. Here, copper ions can be diffused by the first, second, and third heat treatments. At this point, the copper ions can be removed by the silane gas. This process can be repeated to form multiple TiSiN layers as needed.

Referring to FIG. 5, an aluminum layer 70 can be formed on the TiSiN layer 61.

Since the TiSiN layers 51 and 61 formed on the copper metal line 30 are densely formed, the layers can not only inhibit copper ions of the copper metal line 30 from diffusing, but also enhance adhesive force when the aluminum line 71 is connected to the copper metal line 30.

Referring to FIG. 6, the aluminum layer 70, the first TiN layer 40, and the TiSiN layers 51 and 61 are etched to form a metal pad 71 of aluminum.

Accordingly, the aluminum pad 71 and the copper metal line 30 are electrically connected with each other via the diffusion barrier layer.

A method for forming a metal line of a semiconductor device according to an embodiment forms a TiSiN layer including a plurality of layers as a diffusion barrier layer on a copper metal line to inhibit copper ions of the copper metal line from diffusing into an aluminum pad.

Also, an adhesive characteristic between the copper metal line and the aluminum line can be enhanced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristics is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the components parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for forming a metal line of a semiconductor device, the method comprising:
forming a trench in an interlayer insulating layer formed on a semiconductor substrate;
forming a copper metal line in the trench;
forming a diffusion barrier layer including at least one barrier layer on the interlayer insulating layer and the copper metal line; and
forming a metal pad on the diffusion barrier layer.

2. The method according to claim 1, wherein the diffusion barrier layer comprises a TiSiN layer, and the metal pad is formed of aluminum.

3. The method according to claim 1, wherein the diffusion barrier layer comprises a TiN layer and at least one TiSiN layer on the TiN layer.

4. The method according to claim 1, wherein forming the diffusion barrier layer comprises:
performing an annealing process on the semiconductor substrate including the copper metal line using a hydrogen gas;
heating the semiconductor substrate and depositing a first TiN layer through a first heat treatment;
heating the semiconductor substrate including the first TiN layer and depositing a second TiN layer through a second heat treatment;
injecting a silane gas (SiH₄) onto the semiconductor substrate on which the first and second TiN layers have been deposited to form a first TiSiN layer;
heating the semiconductor substrate including the first TiSiN layer and depositing a third TiN layer through a third heat treatment; and
injecting a silane gas (SiH₄) onto the semiconductor substrate including the third TiN layer to form a second TiSiN layer.

5. The method according to claim 4, wherein the annealing process using the hydrogen gas is performed at temperature of 100-350° C. and pressure of 1-25 Torr for 5-45 seconds.

6. The method according to claim 4, wherein the heating of the semiconductor substrate for depositing TiN is performed at pressure of 1-10 Torr for 5-15 seconds.

7. The method according to claim 4, wherein the first heat treatment is performed at temperature of 100-350° C. and pressure of 1-5 Torr for 5-32 seconds.

8. The method according to claim 4, wherein injecting a silane gas comprises injecting 10-40 sccm of the silane gas at temperature of 100-350° C.

9. The method according to claim 4, further comprising maintaining the semiconductor substrate in a stand-by chamber for one minute after the injecting of the silane gas (SiH₄) onto the semiconductor substrate on which the first and second TiN layers have been deposited to form the first TiSiN layer.

10. A metal line of a semiconductor device comprising:
a semiconductor substrate including an interlayer insulating layer;
a trench formed in the interlayer insulating layer;
a copper metal line formed in the trench;
a diffusion barrier layer formed on the copper metal line; and
a metal pad formed on the diffusion barrier layer,
wherein the diffusion barrier layer includes a TiN layer and at least one TiSiN layer formed on the TiN layer.

11. The metal line according to claim 10, wherein the metal pad is formed of aluminum.

12. The metal line according to claim 10, wherein the diffusion barrier layer comprises a TiN layer, a first TiSiN layer, and a second TiSiN layer.
